(19) United States
(12) Patent Application Publication
(10) Pub. No.: US 2021/0384305 A1
(43) Pub. Date: Dec. 9, 2021

(54) THIN-FILM TRANSISTOR, ARRAY BASE PLATE AND DISPLAY PANEL

(71) Applicants: Chongqing BOE Optoelectronics Technology Co., Ltd., Chongqing (CN); BOE Technology Group Co., Ltd., Beijing (CN)

(72) Inventors: Jun Wang, Beijing (CN); Zhonghao Huang, Beijing (CN); Maokun Tian, Beijing (CN); Yongliang Zhao, Beijing (CN)

(73) Assignees: Chongqing BOE Optoelectronics Technology Co., Ltd., Chongqing (CN); BOE Technology Group Co., Ltd., Beijing (CN)

(21) Appl. No.: 17/182,521

(22) Filed: Feb. 23, 2021

(30) Foreign Application Priority Data
Jun. 8, 2020 (CN) 202021035086.9

(51) Int. Cl. H01L 29/417; H01L 27/12

(52) U.S. Cl. CPC H01L 29/41733; H01L 27/124

(57) ABSTRACT

A thin-film transistor, an array base plate and a display panel, wherein the thin-film transistor includes a semiconductor layer, a source metal layer and a drain metal layer, the semiconductor layer includes a first region, a first end of the first region extends in a first direction to form a second region, and a second end of the first region extends in the first direction to form a third region; and both of the source metal layer and the drain metal layer extend in the first direction, the source metal layer covers the first end and at least part of the second region, and the drain metal layer covers the second end and at least part of the third region.

### CROSS REFERENCE TO RELEVANT APPLICATIONS

The present disclosure claims the priority of the Chinese patent application filed on Jun. 8, 2020 before the Chinese Patent Office with the application number of 202021035086.9 and the title of “THIN-FILM TRANSISTOR, ARRAY BASE PLATE AND DISPLAY PANEL”, which is incorporated herein in its entirety by reference.

### TECHNICAL FIELD

The present disclosure relates to the technical field of displaying, and particularly relates to a thin-film transistor, an array base plate and a display panel.

### BACKGROUND

Thin-film transistors are one of field-effect transistors. The process of fabricating them generally comprises depositing various thin films on a base plate, such as a semiconductor active layer, a dielectric layer and a metal electrode layer. Thin-film transistors are of vital importance for the performance of display devices. In a thin-film transistor the semiconductor layer is an elongate semiconductor layer, and a source metal layer and a drain metal layer of the thin-film transistor cover the two ends of the semiconductor layer.

### SUMMARY

The purpose of the embodiments of the present disclosure is to provide a thin-film transistor, an array base plate and a display panel.

An embodiment of the present disclosure discloses a thin-film transistor, wherein the thin-film transistor comprises a semiconductor layer, a source metal layer and a drain metal layer, the semiconductor layer comprises a first region, a first end of the first region extends in a first direction to form a second region, and a second end of the first region extends in the first direction to form a third region; and

both of the source metal layer and the drain metal layer extend in the first direction, the source metal layer covers the first end and at least part of the second region, and the drain metal layer covers the second end and at least part of the third region.

In an alternative embodiment, an area of the first end and the at least part of the second region that are covered by the source metal layer is a first area, an area of the second end and the at least part of the third region that are covered by the drain metal layer is a second area, and the first area is equal to the second area.

In an alternative embodiment, the second region is on a first side or a second side of the first region, and the third region is on the first side or the second side of the first region, wherein the first side of the first region and the second side of the first region are opposite.

In an alternative embodiment, the second region and the third region are two second regions and two third regions, one of the two second regions and one of the two third regions are on a first side of the first region, and the other one of the two second regions and the other one of the two third regions are on a second side of the first region, wherein the first side of the first region and the second side of the first region are opposite.

In an alternative embodiment, the second region and the third region are elongate regions.

In an alternative embodiment, the source metal layer covers the second region, the drain metal layer covers the third region, a width of the second region is less than a width of the source metal layer, and a width of the third region is less than a width of the drain metal layer.

In an alternative embodiment, a difference between the width of the source metal layer and the width of the second region and a difference between a width of the drain metal layer and a width of the third region are greater than a preset width.

In an alternative embodiment, the source metal layer and the drain metal layer are fabricated by using an exposure machine, and the preset width is related to an alignment precision and a line-width precision of the exposure machine.

In an alternative embodiment, the first region extends in a second direction, wherein the second direction is perpendicular to the first direction.

In an alternative embodiment, one of the source metal layer and the drain metal layer is for being connected to a pixel electrode.

An embodiment of the present disclosure further discloses an array base plate, wherein the array base plate comprises the thin-film transistor stated above.

An embodiment of the present disclosure further discloses a display panel, wherein the display panel comprises the array base plate stated above.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly introduced below. Apparently, the figures that are described below are merely embodiments of the present disclosure, and a person skilled in the art can obtain other figures according to these figures without paying creative work.

FIG. 1 is a schematic structural diagram of an embodiment of the thin-film transistor according to the present disclosure;

FIG. 2 is a schematic diagram of a C-V characteristic curve of the MIS structure;

FIG. 3 is a schematic structural diagram of another embodiment of the thin-film transistor according to the present disclosure;

FIG. 4 is a schematic structural diagram of yet another embodiment of the thin-film transistor according to the present disclosure; and

FIG. 5 is schematic diagrams of the Id-Vg curves of a thin-film transistor in the related art and the thin-film transistor according to an embodiment of the present disclosure.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

Referring to FIG. 1, FIG. 1 shows a schematic structural diagram of an embodiment of the thin-film transistor according to the present disclosure. The thin-film transistor may particularly comprise a semiconductor layer 1, a source metal layer 2 and a drain metal layer 3. The semiconductor layer 1 comprises a first region 11. A first end 12 of the first region 11 extends in a first direction to form a second region 13. A second end 14 of the first region 11 extends in the first direction to form a third region 15. Both of the source metal layer 2 and the drain metal layer 3 extend in the first direction. The source metal layer 2 covers the first end 12 and at least part of the second region 13. The drain metal layer 3 covers the second end 14 and at least part of the third region 15. In FIG. 1, 4 indicates a grid layer. In FIG. 1, the source metal layer 2 and the drain metal layer 3 are provided in the same layer, the semiconductor layer 1 is provided between the grid layer 4, the source metal layer 2 and the drain metal layer 3, a grid insulating layer is provided between the grid layer 4 and the semiconductor layer 1, and the grid insulating layer is not shown in FIG. 1.

The covering of the at least part of the second region 13 by the source metal layer 2 may be that the source metal layer 2 covers part of the second region 13 that is adjacent to the first end 12, or that the source metal layer 2 covers the second region 13. The covering of the at least part of the third region 15 by the drain metal layer 3 may be that the drain metal layer 3 covers part of the third region 15 that is adjacent to the second end 14, or that the drain metal layer 3 covers the third region 15.

Particularly, the first end 12 and the second end 14 of the first region 11 are not doped or are not heavily doped, and the contacts between the first end 12 of the first region 11 and the source metal layer 2 and between the second end 14 of the first region 11 and the drain metal layer 3 are Schottky contact.

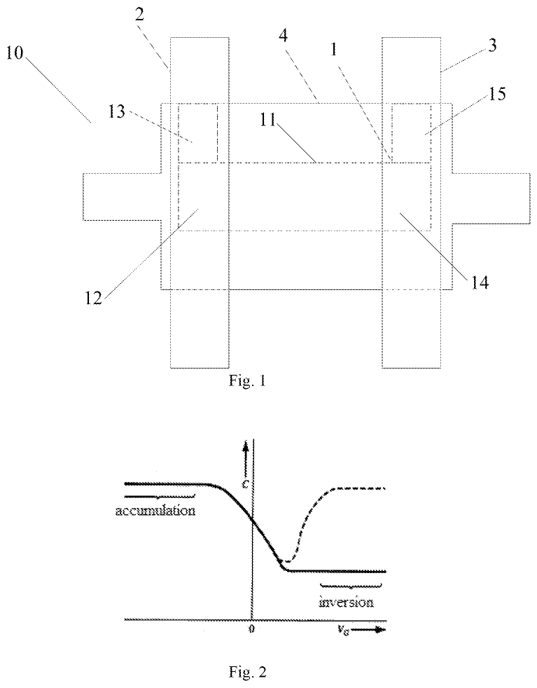

In the structure of a metal-insulator semiconductor (MIS) without source and drain, if the electrodes of the MIS structure are applied a cut-in bias voltage, the charge carrier on the surfaces of the electrodes in the MIS structure is the minority carrier of the semiconductor, and the speed at which the charge carrier forms the inversion layer is very low, and is generally 10\hat{ }−3 s. The capacitance-voltage characteristic curve (C-V characteristic curve) of the MIS structure is shown in FIG. 2. It can be known from the C-V characteristic curve in FIG. 2 that, when the MIS structure is at a low frequency (for example, a frequency of 5 Hz to 100 Hz), the capacitance increases with increase of the voltage, and when the MIS structure is at a high frequency (for example, a frequency of 1 MHz), the inversion layer cannot be formed timely, and the capacitance does not increase with increase of the voltage. In FIG. 2, the dotted line is the C-V characteristic curve of the MIS structure at a low frequency, and the solid line is the C-V characteristic curve of the MIS structure at a high frequency. However, in practical applications, the working frequencies of thin-film transistors having a source and a drain may be on the scale of KHz (kilohertz) or MHz (megahertz), which indicates that, when the thin-film transistors are in the on state, the charge carrier forming the inversion layer is not from the semiconductor substrate, but is from the source metal layer 2 and the drain metal layer 3.

In the present disclosure, the source metal layer 2 does not only cover the first end 12 of the first region 11, but also covers at least part of the second region 13, and the drain metal layer 3 does not only cover the second end 14 of the first region 11, but also covers at least part of the third region 15. Accordingly, even if the first end 12 and the second end 14 of the first region 11 are not heavily doped, because the second region 13 and the third region 15 greatly increase the contact area between the source metal layer 2 and the drain metal layer 3 and the semiconductor layer 1, within the same duration, the increased contact area enables, when the thin-film transistor is in the on state, the charge carrier from the source metal layer 2 and the drain metal layer 3 to the semiconductor layer to be increased, the contact potential barrier to be reduced, the speed at which the charge carrier forms the inversion layer in the thin-film transistor to be increased, the subthreshold swing (SS) of the thin-film transistor to be reduced, and the switching performance of the thin-film transistor be improved, and the reduction of the contact potential barrier can enable the contact resistance between the semiconductor layer 1 and the source metal layer 2 and the drain metal layer 3 in the thin-film transistor to be reduced, and the on-state current (Iₒₙ) and the mobility of the thin-film transistor to be increased.

Optionally, the first region 11 may extend in a second direction, wherein the second direction is perpendicular to the first direction.

Optionally, the surface of the at least part of the second region 13 that contacts the source metal layer 2 may be not doped or may be doped, and the surface of the at least part of the third region 15 that contacts the drain metal layer 3 may be not doped or may be doped. Because the second region 13 and the third region 15 greatly increase the contact area between the source metal layer 2 and the drain metal layer 3 and the semiconductor layer 1, no matter whether the surface of the at least part of the second region 13 that contacts the source metal layer 2 and the surface of the at least part of the third region 15 that contacts the drain metal layer 3 are doped, the contact potential barrier between the source metal layer 2 and the drain metal layer 3 and the semiconductor layer 1 can be effectively reduced. Furthermore, if the surface of the at least part of the second region 13 that contacts the source metal layer 2 and the surface of the at least part of the third region 15 that contacts the drain metal layer 3 are doped, the contact potential barrier between the source metal layer 2 and the drain metal layer 3 and the semiconductor layer 1 can be further reduced.

Optionally, the shape and the area of the second region 13 and the shape and the area of the third region 15 may be the same or different, and, if the area of the first end 12 and the at least part of the second region 13 that are covered by the source metal layer 2 is a first area, and the area of the second end 14 and the at least part of the third region 15 that are covered by the drain metal layer 3 is a second area, then the first area is equal to the second area. Because the first area and the second area are equal, it can be ensured that, in the thin-film transistor, the contact potential barrier between the source metal layer 2 and the semiconductor layer 1 and the contact potential barrier between the drain metal layer 3 and the semiconductor layer 1 are equal.

If the area of the first end 12 that is covered by the source metal layer 2 is equal to the area of the second end 14 that is covered by the drain metal layer 3, then the area of the at least part of the second region 13 that is covered by the source metal layer 2 is equal to the area of the at least part of the third region 15 that is covered by the drain metal layer 3. If the area of the first end 12 that is covered by the source metal layer 2 is not equal to the area of the second end 14 that is covered by the drain metal layer 3, then the area of the at least part of the second region 13 that is covered by the source metal layer 2 is not equal to the area of the at least part of the third region 15 that is covered by the drain metal layer 3.

Optionally, the second region 13 may be on a first side or a second side of the first region 11, and the third region 15 may be on the first side or the second side of the first region 11, wherein the first side of the first region 11 and the second side of the first region 11 are opposite. Therefore, the second region 13 and the third region 15 may be on the same side of the first region 11, and may also be on different sides of the first region 11. As shown in FIG. 1, when the second region 13 and the third region 15 are on the same side of the first region 11, the planar area that is occupied by the semiconductor layer 1 can be small.

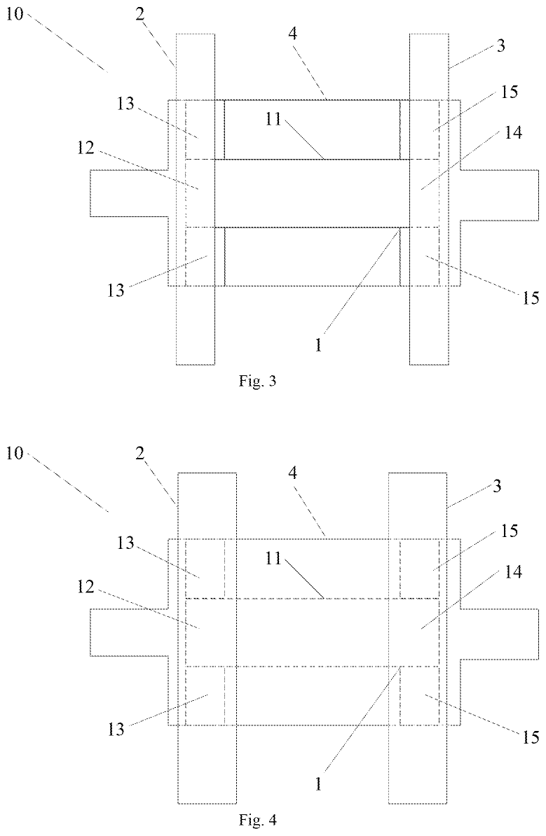

Optionally, as shown in FIGS. 3 and 4, the second region 13 and the third region 15 may be two second regions 13 and two third regions 15, one of the two second regions 13 and one of the two third regions 15 are provided on a first side of the first region 11, and the other one of the two second regions 13 and the other one of the two third regions 15 are provided on a second side of the first region 11, wherein the first side of the first region 11 and the second side of the first region 11 are opposite. Therefore, the source metal layer 2 covers the first end 12 and the two second regions 13 on the two sides of the first region 11, and the drain metal layer 3 covers the second end 14 and the two third regions 15 on the two sides of the first region 11, which enables the contact area between the source metal layer 2 and the drain metal layer 3 and the semiconductor layer 1 to be largest. FIG. 3 is a schematic structural diagram in which the source metal layer 2 covers part of the second regions 13 and the drain metal layer 3 covers part of the third regions 15.

Optionally, the shapes and the areas of the two second regions 13 may be the same or different, and the shapes and the areas of the two third regions 15 may be the same or different.

Optionally, in the case that the source metal layer 2 and the drain metal layer 3 are elongate metal layers, the second region 13 and the third region 15 may be elongate regions. That facilitates to set the area of the part of the second region 13 that is covered by the source metal layer 2 and the area of the part of the third region 15 that is covered by the drain metal layer 3.

Optionally, as shown in FIG. 4, in the case that the source metal layer 2 covers the second region 13 and the drain metal layer 3 covers the third region 15, the width of the second region 13 may be less than the width of the source metal layer 2, and the width of the third region 15 may be less than the width of the drain metal layer 3. Accordingly, because the width of the source metal layer 2 is greater than the width of the second region 13, that can facilitate the source metal layer 2 to completely cover the second region 13, and because the width of the drain metal layer 3 is greater than the width of the third region 15, that can facilitate the drain metal layer 3 to completely cover the third region 15.

Optionally, the difference between the width of the source metal layer 2 and the width of the second region 13 and the difference between the width of the drain metal layer 3 and the width of the third region 15 are greater than a preset width. Accordingly, when the source metal layer 2 and the drain metal layer 3 are fabricated by using an exposure machine, the exposure machine for fabricating the source metal layer 2 and the drain metal layer 3 can have an alignment margin of the preset width, to ensure that the exposure machine completely covers the second region 13 with the source metal layer 2 and completely covers the third region 15 with the drain metal layer 3. The preset width may be related to the alignment precision and the line-width precision of the exposure machine for fabricating the source metal layer 2 and the drain metal layer 3. For example, if the alignment precision of the exposure machine is 0.8 μm and the line-width precision is 1 μm, then the preset width may be 0.8*2+1=2.6 μm.

Optionally, the semiconductor layer 1 may be fabricated by using an exposure/development process or another process, which is not limited in the present disclosure.

Optionally, one of the source metal layer 2 and the drain metal layer 3 is used to be connected to a pixel electrode. The planar area that is occupied by the metal layer (the source metal layer 2 or the drain metal layer 3) that is used to be connected to the pixel electrode should be small to the largest extent, to enable the area that the pixel electrode can occupy in the pixel array to be large to the largest extent, which facilitates to increase the planar area that is occupied by the pixel electrode.

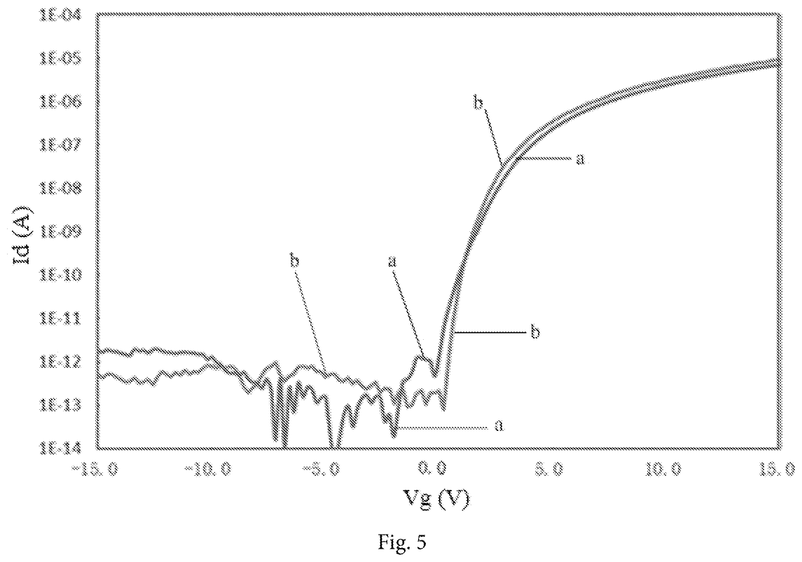

FIG. 5 is a drain current-grid voltage (Id-Vg) curve a of a thin-film transistor in the related art (wherein the semiconductor layer is an elongate semiconductor layer, and the source metal layer and the drain metal layer of the thin-film transistor cover the two ends of the semiconductor layer), and an Id-Vg curve b of the thin-film transistor according to an embodiment the present disclosure when the second region 13 and the third region 15 in the thin-film transistor are two second regions 13 and two third regions 15. The thin-film transistor according to the embodiment of the present disclosure and the thin-film transistor in the related art in FIG. 5 merely differ in the shapes of the semiconductor layers 1, and the other fabrication parameters are the same. After a large quantity of the thin-film transistors according to the embodiment of the present disclosure and the thin-film transistors in the related art in FIG. 5 have been tested, the average values of the obtained Iₒₙ, off-state currents (I_{off}), threshold voltages (Vₜₕ), mobilities and SSs are shown in Table 6. Table 6 is a table of the characteristic values of the thin-film transistor in the related art and the thin-film transistor according to the embodiment of the present disclosure. It can be known from Table 6 that, comparing the thin-film transistor according to the embodiment of the present disclosure and the thin-film transistor in the related art, the Iₒₙ is increased by 28.4%, the mobility is increased by 26.7%, and the SS is reduced by 32.9%.

TABLE 6

| | Iₒₙ | I_{off} | Vₜₕ | mobility | SS |
|---|---|---|---|---|---|
| Thin-film transistor of curve b | 9.11 | 0.29 | 2.33 | 10.85 | 0.53 |
| Thin-film transistor of curve a | 7.09 | 0.33 | 2.48 | 8.56 | 0.79 |

The thin-film transistor according to embodiments of the present disclosure has the following advantages. By setting that, in the semiconductor layer 1, the first end 12 of the first region 11 extends in the first direction to form the second region 13, and the second end 14 of the first region 11 extends in the first direction to form the third regions 15, and by setting that the source metal layer 2 covers the first end 12 and at least part of the second region 13, and the drain metal layer 3 covers the second end 14 and at least part of the third region 15, wherein both of the source metal layer 2 and the drain metal layer 3 extend in the first direction, wherein the area of the first end 12 and the at least part of the second region 13 that are covered by the source metal layer 2 is equal to the area of the second end 14 and the at least part of the third region 15 that are covered by the drain metal layer 3, it is realized that the source metal layer 2 does not only cover the first end 12 of the first region 11, but also covers at least part of the second region 13, and the drain metal layer 3 does not only cover the second end 14 of the first region 11, but also covers at least part of the third region 15, which ensures that the contact potential barrier between the source metal layer 2 and the semiconductor layer 1 and the contact potential barrier between the drain metal layer 3 and the semiconductor layer 1 are equal. Furthermore, no matter whether the first end 12 and the second end 14 of the first region 11 are doped or not, because the second region 13 and the third region 15 greatly increase the contact area between the source metal layer 2 and the drain metal layer 3 and the semiconductor layer 1, the contact potential barriers are effectively reduced, which can reduce the contact resistance between the semiconductor layer 1 and the source metal layer 2 and the drain metal layer 3 in the thin-film transistor and increase the speed at which the charge carrier forms the inversion layer in the thin-film transistor.

An embodiment of the present disclosure further discloses an array base plate, comprising the thin-film transistor stated above.

The array base plate according to embodiments of the present disclosure has the following advantages. By setting that, in each of the thin-film transistors, in the semiconductor layer 1, the first end 12 of the first region 11 extends in the first direction to form the second region 13, and the second end 14 of the first region 11 extends in the first direction to form the third regions 15, and by setting that the source metal layer 2 covers the first end 12 and at least part of the second region 13, and the drain metal layer 3 covers the second end 14 and at least part of the third region 15, wherein both of the source metal layer 2 and the drain metal layer 3 extend in the first direction, wherein the area of the first end 12 and the at least part of the second region 13 that are covered by the source metal layer 2 is equal to the area of the second end 14 and the at least part of the third region 15 that are covered by the drain metal layer 3, it is realized that the source metal layer 2 does not only cover the first end 12 of the first region 11, but also covers at least part of the second region 13, and the drain metal layer 3 does not only cover the second end 14 of the first region 11, but also covers at least part of the third region 15, which ensures that the contact potential barrier between the source metal layer 2 and the semiconductor layer 1 and the contact potential barrier between the drain metal layer 3 and the semiconductor layer 1 are equal. Furthermore, no matter whether the first end 12 and the second end 14 of the first region 11 are doped or not, because the second region 13 and the third region 15 greatly increase the contact area between the source metal layer 2 and the drain metal layer 3 and the semiconductor layer 1, the contact potential barriers are effectively reduced, which can reduce the contact resistance between the semiconductor layer 1 and the source metal layer 2 and the drain metal layer 3 in the thin-film transistor and increase the speed at which the charge carrier forms the inversion layer in the thin-film transistor.

An embodiment of the present disclosure further discloses a display panel, comprising the array base plate stated above.

The display panel according to embodiments of the present disclosure has the following advantages. By setting that, in each of the thin-film transistors in the array base plate, in the semiconductor layer 1, the first end 12 of the first region 11 extends in the first direction to form the second region 13, and the second end 14 of the first region 11 extends in the first direction to form the third regions 15, and by setting that the source metal layer 2 covers the first end 12 and at least part of the second region 13, and the drain metal layer 3 covers the second end 14 and at least part of the third region 15, wherein both of the source metal layer 2 and the drain metal layer 3 extend in the first direction, wherein the area of the first end 12 and the at least part of the second region 13 that are covered by the source metal layer 2 is equal to the area of the second end 14 and the at least part of the third region 15 that are covered by the drain metal layer 3, it is realized that the source metal layer 2 does not only cover the first end 12 of the first region 11, but also covers at least part of the second region 13, and the drain metal layer 3 does not only cover the second end 14 of the first region 11, but also covers at least part of the third region 15, which ensures that the contact potential barrier between the source metal layer 2 and the semiconductor layer 1 and the contact potential barrier between the drain metal layer 3 and the semiconductor layer 1 are equal. Furthermore, no matter whether the first end 12 and the second end 14 of the first region 11 are doped or not, because the second region 13 and the third region 15 greatly increase the contact area between the source metal layer 2 and the drain metal layer 3 and the semiconductor layer 1, the contact potential barriers are effectively reduced, which can reduce the contact resistance between the semiconductor layer 1 and the source metal layer 2 and the drain metal layer 3 in the thin-film transistor and increase the speed at which the charge carrier forms the inversion layer in the thin-film transistor.

Regarding the embodiments of the array base plate and the display panel, because they comprise the thin-film transistor stated above, they are described simply, and the related parts may refer to the description on the embodiments of the thin-film transistor.

The embodiments of the description are described in the mode of progression, each of the embodiments emphatically describes the differences from the other embodiments, and the same or similar parts of the embodiments may refer to each other.

Although alternative embodiments of the embodiments of the present disclosure have been described, once a person skilled in the art has known the substantial inventive concept, he may make further variations and modifications on those embodiments. Therefore, the appended claims are intended to be interpreted as including the alternative embodiments and all of the variations and modifications that fall within the scope of the embodiments of the present disclosure.

Finally, it should also be noted that, in the present text, relation terms such as first and second are merely intended to distinguish one entity or operation from another entity or operation, and that does not necessarily require or imply that those entities or operations have therebetween any such actual relation or order. Furthermore, the terms “include”, “comprise” or any variants thereof are intended to cover non-exclusive inclusions, so that processes, methods, articles or terminal devices that include a series of elements do not only include those elements, but also include other elements that are not explicitly listed, or include the elements that are inherent to such processes, methods, articles or terminal devices. Unless further limitation is set forth, an element defined by the wording “comprising a . . . ” does not exclude additional same element in the process, method, article or terminal device comprising the element.

The thin-film transistor, the array base plate and the display panel according to the present disclosure have been described in detail above. The principle and the embodiments of the present disclosure are described herein with reference to the particular examples, and the description of the above embodiments is merely intended to facilitate to understand the present disclosure. Moreover, for a person skilled in the art, according to the present disclosure, the particular embodiments and the range of application may be varied. In conclusion, the contents of the description should not be understood as limiting the present disclosure.

The above-described device embodiments are merely illustrative, wherein the units that are described as separate components may or may not be physically separate, and the components that are displayed as units may or may not be physical units; in other words, they may be located at the same one location, and may also be distributed to a plurality of network units. Part or all of the modules may be selected according to the actual demands to realize the purposes of the solutions of the embodiments. A person skilled in the art can understand and implement the technical solutions without paying creative work.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “comprise” does not exclude elements or steps that are not listed in the claims. The word “a” or “an” preceding an element does not exclude the existing of a plurality of such elements. The present disclosure may be implemented by means of hardware comprising several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail by referring to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A thin-film transistor, wherein the thin-film transistor comprises a semiconductor layer, a source metal layer and a drain metal layer, the semiconductor layer comprises a first region, a first end of the first region extends in a first direction to form a second region, and a second end of the first region extends in the first direction to form a third region; and
both of the source metal layer and the drain metal layer extend in the first direction, the source metal layer covers the first end and at least part of the second region, and the drain metal layer covers the second end and at least part of the third region.

2. The thin-film transistor according to claim 1, wherein an area of the first end and the at least part of the second region that are covered by the source metal layer is a first area, an area of the second end and the at least part of the third region that are covered by the drain metal layer is a second area, and the first area is equal to the second area.

3. The thin-film transistor according to claim 1, wherein the second region is on a first side or a second side of the first region, and the third region is on the first side or the second side of the first region, wherein the first side of the first region and the second side of the first region are opposite.

4. The thin-film transistor according to claim 1, wherein the second region and the third region are two second regions and two third regions, one of the two second regions and one of the two third regions are on a first side of the first region, and the other one of the two second regions and the other one of the two third regions are on a second side of the first region, wherein the first side of the first region and the second side of the first region are opposite.

5. The thin-film transistor according to claim 1, wherein the second region and the third region are elongate regions.

6. The thin-film transistor according to claim 1, wherein the source metal layer covers the second region, the drain metal layer covers the third region, a width of the second region is less than a width of the source metal layer, and a width of the third region is less than a width of the drain metal layer.

7. The thin-film transistor according to claim 6, wherein a difference between the width of the source metal layer and the width of the second region and a difference between a width of the drain metal layer and a width of the third region are greater than a preset width.

8. The thin-film transistor according to claim 7, wherein the source metal layer and the drain metal layer are fabricated by using an exposure machine, and the preset width is related to an alignment precision and a line-width precision of the exposure machine.

9. The thin-film transistor according to claim 1, wherein the first region extends in a second direction, wherein the second direction is perpendicular to the first direction.

10. The thin-film transistor according to claim 1, wherein one of the source metal layer and the drain metal layer is for being connected to a pixel electrode.

11. An array base plate, wherein the array base plate comprises the thin-film transistor according to claim 1.

12. A display panel, wherein the display panel comprises the array base plate according to claim 11.
